(19) United States
(12) Patent Application Publication
(10) Pub. No.: US 2026/0182129 A1
(43) Pub. Date: Jun. 25, 2026

(54) DISPLAY APPARATUS HAVING LIGHT-EMITTING DEVICES AND COLOR FILTERS

(71) Applicant: LG Display Co., Ltd., Seoul (KR)

(72) Inventor: Yeonsuk KANG, Paju-si (KR)

(73) Assignee: LG Display Co., Ltd., Seoul (KR)

(21) Appl. No.: 19/180,075

(22) Filed: Apr. 15, 2025

(30) Foreign Application Priority Data
Dec. 19, 2024 (KR) 10-2024-0191443

(51) Int. Cl. H10H 29/855; H10H 29/85; H10H 29/856

(52) U.S. Cl. CPC H10H 29/8552; H10H 29/8517; H10H 29/856

(57) ABSTRACT

A display apparatus including light-emitting devices and color filters is provided. The light-emitting devices and the color filters can be stacked on emission areas of a device substrate. For example, each of the color filters can overlap one of the emission areas. A pixel lens can be disposed on one of the color filters. A lower surface of the pixel lens toward the device substrate can have a larger size than the corresponding emission area. An optical pattern covering an edge of the pixel lens can be disposed between the emission areas. The optical pattern can have a stacked structure of a reflective pattern and a light-blocking pattern. The amount of light passing through the color filter overlapping with the pixel lens can be smaller than the amount of light passing through adjacent color filter.

### CROSS-REFERENCE TO RELATED APPLICATIONS

This application claims the benefit of Korean Patent Application No. 10-2024-0191443, filed on Dec. 19, 2024, which is hereby incorporated by reference as if fully set forth herein.

### BACKGROUND

### Technical Field

The present disclosure relates to a display apparatus in which light-emitting devices and color filters are stacked on emission areas of a device substrate.

### Discussion of the Related Art

Generally, a display apparatus provides an image to a user. For example, the display apparatus can include light-emitting devices disposed on emission areas of a device substrate. Each of the light-emitting devices can emit light. For example, each of the light-emitting devices can include a light-emitting unit disposed between a first electrode and a second electrode.

Each of the emission areas can realize a specific color using a color filter. For example, light generated by the light-emitting unit of each emission area can be emitted through the color filter of the corresponding emission area. The light passing through each color filter can display a different color from the light passing through adjacent color filter. For example, each of the color filters can be one of a red color filter realizing red color, a green color filter realizing green color, and a blue color filter realizing blue color.

### SUMMARY

Accordingly, embodiments of the present disclosure are directed to a display apparatus having light-emitting devices and color filters that substantially obviates one or more of the problems due to limitations and disadvantages of the related art.

An aspect of the present disclosure is to provide a display apparatus capable of improving the overall luminance of the image realized using the color filter.

Another aspect of the present disclosure is to provide a display apparatus capable of reducing a difference in the amount of light passing through each color filter, without a change in color coordinates.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display apparatus comprises a device substrate. The device substrate includes emission areas. Light-emitting devices are disposed on the emission areas of the device substrate. Color filters are disposed on the light-emitting devices. The color filters overlap the emission areas. A pixel lens is disposed on one of the color filters. A surface of the pixel lens opposite to the device substrate has a convex shape. An edge of the pixel lens is covered by an optical pattern. The optical pattern is disposed in a non-emission area that is a region between the emission areas. An optical planarization layer is disposed on the color filters, the pixel lens and the optical pattern. The optical pattern includes a reflective pattern and a light-blocking pattern. The light-blocking pattern is disposed on the reflective pattern.

In another aspect, a display apparatus comprises a device substrate. A first light-emitting device is disposed on a first emission area of the device substrate. A second light-emitting device is disposed on a second emission area of the device substrate. A first color filter is disposed on the first light-emitting device. The first color filter overlaps the first emission area. A second color filter is disposed on the second light-emitting device. The second color filter overlaps the second emission area. An optical planarization layer is disposed on the first color filter. The optical planarization layer extends on the second color filter. A pixel lens is disposed between the second color filter and the optical planarization layer. A surface of the pixel lens toward the optical planarization layer has a convex shape. An optical pattern is disposed between the pixel lens and the optical planarization layer. The optical pattern includes a reflective pattern and a light-blocking pattern, which are sequentially stacked. The first emission area and the second emission area are disposed outside the optical pattern.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain principles of the present disclosure. In the drawings:

FIG. 1 is a view schematically showing a display apparatus according to an embodiment of the present disclosure;

FIG. 2 is an enlarged view of K1 region in FIG. 1;

FIG. 3 is a view showing a circuit of a pixel area in the display apparatus according to the embodiment of the present disclosure;

FIG. 4 is a view taken along I-I′ of FIG. 2;

FIG. 5 is an enlarged view of K2 region in FIG. 4; and

FIGS. 6 to 9 are views showing the display apparatus according to another embodiment of the present disclosure.

### DETAILED DESCRIPTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure may be embodied in other forms and is not limited to the embodiments described below.

In addition, the same or extremely similar elements may be designated by the same reference numerals throughout the specification and in the drawings, the lengths and thickness of layers and regions may be exaggerated for convenience. It will be understood that, when a first element is referred to as being “on” a second element, although the first element may be disposed on the second element so as to come into contact with the second element, a third element may be interposed between the first element and the second element.

Here, terms such as, for example, “first” and “second” may be used to distinguish any one element with another element. However, the first element and the second element may be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” may include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### EMBODIMENT

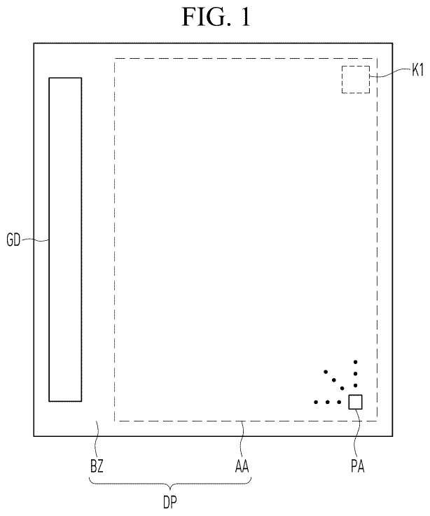

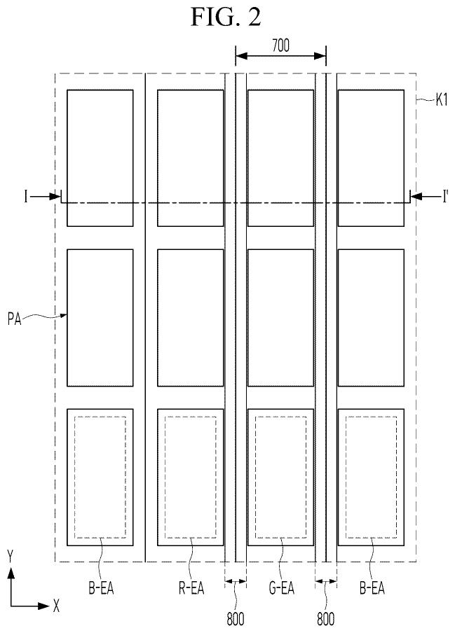

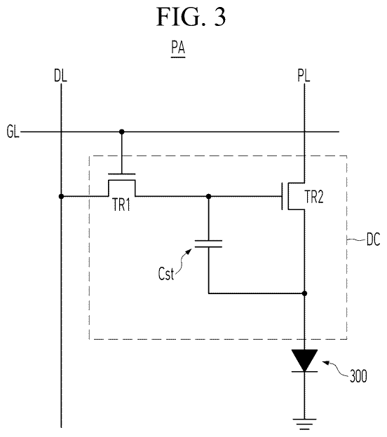

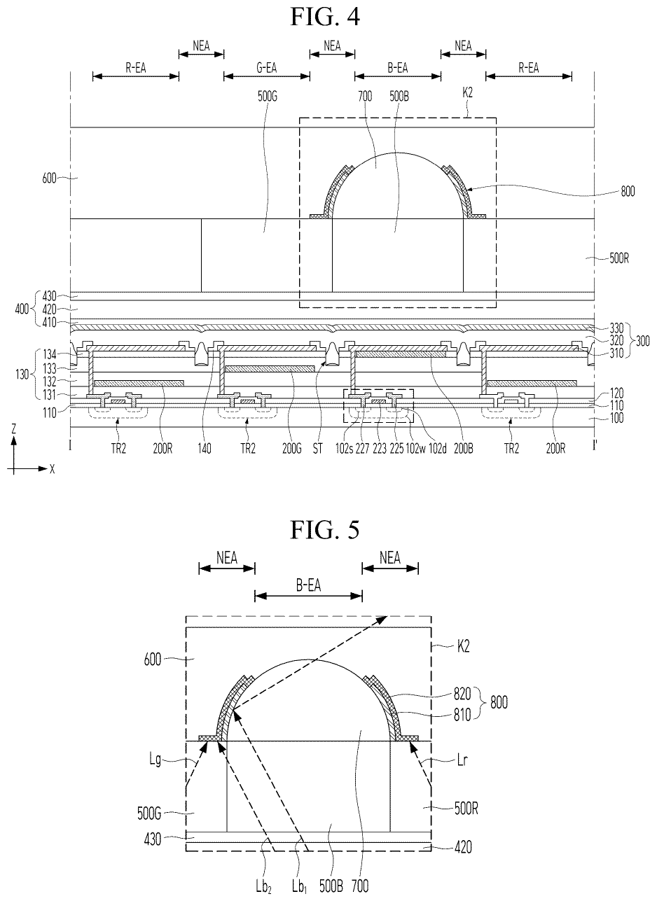

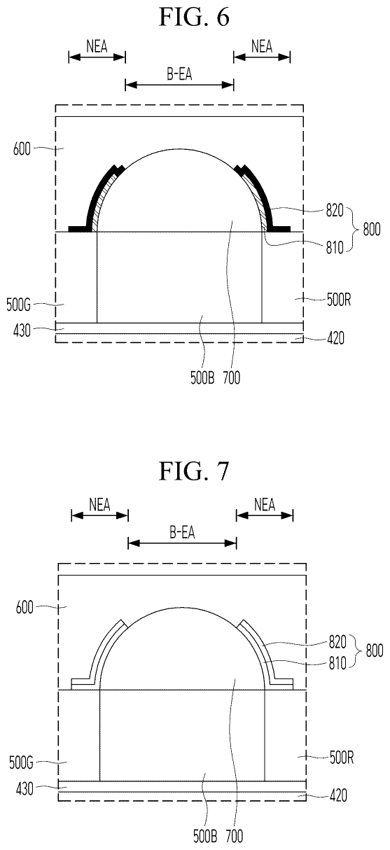

FIG. 1 is a view schematically showing a display apparatus according to an embodiment of the present disclosure. FIG. 2 is an enlarged view of K1 region in FIG. 1. FIG. 3 is a view showing a circuit of a pixel area in the display apparatus according to the embodiment of the present disclosure. FIG. 4 is a view taken along I-I′ of FIG. 2. FIG. 5 is an enlarged view of K2 region in FIG. 4.

Referring to FIGS. 1 to 5, the display apparatus according to the embodiment of the present disclosure can include a display panel DP. The display panel DP can generate an image provided to a user. For example, pixel areas PA can be disposed within the display panel DP. Each of the pixel areas PA can realize a specific color according to signal through signal wirings GL, DL and PL. For example, the image provided to the user can be generated by the pixel areas PA.

The display panel DP can include an active area AA in which the pixel areas PA are disposed, and a bezel area BZ being disposed outside the active area AA. For example, the active area AA can be surrounded by the bezel area BZ. The signal wirings GL, DL and PL can include a gate line GL applying a gate signal, a data line DL applying a data signal, and a power voltage supply line PL supplying a power voltage. A gate driver GD electrically connected to the gate line GL, a data driver DD electrically connected to the data line DL, and a power unit PU electrically connected to the power voltage supply line PL can be disposed outside the active area AA. At least one of the gate driver GD, the data driver DD and the power unit PU can be disposed on the bezel area BZ. For example, the display apparatus according to the embodiment of the present disclosure can be a GIP (Gate In Panel) type display apparatus in which the gate driver GD is formed in the bezel area BZ.

A driving circuit DC electrically connected to the signal wirings GL, DL and PL, and a light-emitting device 300 electrically connected to the driving circuit DC can be disposed within each pixel area PA. The driving circuit DC and the light-emitting device 300 of each pixel area PA can be supported by a device substrate 100. The device substrate 100 can include various materials. For example, the device substrate 100 can be a wafer made of a semiconductor material, such as silicon.

The driving circuit DC can supply a driving current corresponding to the data signal to the light-emitting device 300 according to the gate signal using the power voltage. The driving current supplied to the light-emitting device 300 by the driving circuit DC can be maintained for one frame. For example, the driving circuit DC can include a first thin film transistor TR1, a second thin film transistor TR2 and a storage capacitor Cst.

The first thin film transistor TR1 can transmit the data signal to the second thin film transistor TR2 according to the gate signal. For example, the first thin film transistor TR1 can function as a switching thin film transistor. The first thin film transistor TR1 can include a first well region, a first drain region, a first source region, a first gate electrode, a first drain electrode and a first source electrode. For example, the first gate electrode can be electrically connected to the gate line GL, and the first drain electrode can be electrically connected to the date line DL.

The second thin film transistor TR2 can generate the driving current corresponding to the data signal using the power voltage. For example, the second thin film transistor TR2 can function as a driving thin film transistor. The second thin film transistor TR2 can include a second well region 102w, a second drain region 102d, a second source region 102s, a second gate electrode 223, a second drain electrode 225 and a second source electrode 227. For example, the second gate electrode 223 can be electrically connected to the first source electrode, and the second drain electrode 225 can be electrically connected to the power voltage supply line PL.

A voltage of a signal applied to the second gate electrode 223 can be maintained by the storage capacitor Cst for one frame. The storage capacitor Cst can have a stacked structure of capacitor electrodes. For example, the storage capacitor Cst can have a stacked structure of a first capacitor electrode electrically connected to the second gate electrode 233 and a second capacitor electrode electrically connected to the second source electrode 227.

At least one insulating layer 110, 120, 130 and 140 for preventing unnecessary electrical connection can be disposed on the device substrate 100. For example, a gate insulating layer 110, an interlayer insulating layer 120, a device planarization layer 130 and fences 140 can be disposed on the device substrate 100.

The gate insulating layer 110 can be disposed close the device substrate 100. The second gate electrode 223 of each pixel area PA can be insulated from the device substrate 100 by the gate insulating layer 120. For example, an upper surface of the device substrate 100 toward the second gate electrode 223 of each pixel area PA can be covered by the gate insulating layer 120.

The interlayer insulating layer 120 can be disposed on the gate insulating layer 110. The second drain electrode 225 and the second source electrode 227 of each pixel area PA can be insulated from the second gate electrode 223 of the corresponding pixel area PA by the interlayer insulating layer 130. For example, the first gate electrode and the second gate electrode 223 of each pixel area PA disposed on the gate insulating layer 110 can be covered by the interlayer insulating layer 120.

The device planarization layer 130 can be disposed on the interlayer insulating layer 120. A thickness difference due to the driving circuit DC of each pixel area PA can be removed by the device planarization layer 130. For example, the first drain electrode, the first source electrode, the second drain electrode 225 and the second source electrode 227 of each pixel area PA disposed on the interlayer insulating layer 120 can be covered by the device planarization layer 130. An upper surface of the device planarization layer 130 opposite to the device substrate 100 can be flat. The device planarization layer 130 can include a material having a higher fluidity than the gate insulating layer 110 and the interlayer insulating layer 120. For example, the gate insulating layer 110 and the interlayer insulating layer 120 can include an inorganic insulating material, and the device planarization layer 130 can include an organic insulating material.

The light-emitting device 300 of each pixel area PA can be disposed on the upper surface of the device planarization layer 130. The light-emitting device 300 of each pixel area PA can emit light displaying a specific color. For example, the light-emitting device 300 of each pixel area PA can include a first electrode 310, a light-emitting unit 320 and a second electrode 330, which are sequentially stacked on the device planarization layer 130.

The first electrode 310 and the second electrode 330 can include a conductive material. The second electrode 330 can include a different material from the first electrode 310. For example, the first electrode 310 can be a transparent electrode made of a transparent conductive material, such as ITO and IZO, and the second electrode 330 can be a translucent electrode in which a metal, such as silver (Ag) and magnesium (Mg) is thinly formed.

The light-emitting unit 320 can generate light having luminance corresponding to a voltage difference between the first electrode 310 and the second electrode 330. For example, the light-emitting unit 320 can include at least one emission material layer (EML). The light-emitting unit 320 can have a multi-layer structure. For example, the light-emitting unit 320 can include at least one of a hole injection layer (HIL), a hole transport layer (HTL), an electron transport layer (ETL) and an electron injection layer (EIL).

The first electrode 310 of each pixel area PA can be electrically connected to the driving circuit DC of the corresponding pixel area PA. For example, the first electrode 310 of each pixel area PA can be in direct contact with the second source electrode 227 of the corresponding pixel area PA by penetrating the device planarization layer 130. A connection region of the second source electrode 227 and the first electrode 310 in each pixel area PA can be covered by one of the fences 140. The fences 140 can define an emission area R-EA, G-EA and B-EA from which light is emitted in each pixel area PA. A non-emission area NEA from which light is not emitted can be disposed between the emission areas EA. For example, the fences 140 can be disposed in the non-emission area NEA. The first electrode 310 of each pixel area PA can be insulated from the first electrode 310 of adjacent pixel area PA by the fences 140.

A signal applied to the second electrode 330 of each pixel area PA can be the same as a signal applied to the second electrode 330 of adjacent pixel area PA. For example, the second electrode 330 of each pixel area PA can be electrically connected to the second electrode 330 of adjacent pixel area PA. Thus, in the display apparatus according to the embodiment of the present disclosure, the luminance of the light emitted from the emission area R-EA, G-EA and B-EA of each pixel area PA can be determined by the data signal applied to the driving circuit DC of the corresponding pixel area PA.

Light generated by the light-emitting unit 320 of each pixel area PA can display a same color as light generated by the light-emitting unit 320 of adjacent pixel area PA. For example, the light-emitting unit 320 of each pixel area PA can generate white light. The light-emitting unit 320 of each pixel area PA can be formed simultaneously with the light-emitting unit 320 of adjacent pixel area PA.

The image generated by the pixel areas PA can include various colors. The light emitted from the emission area R-EA, G-EA and B-EA of each pixel area PA can display a specific color. For example, the emission area R-EA, G-EA and B-EA of each pixel area PA can be one of a red emission area R-EA emitting red light, a green emission area G-EA emitting green light and a blue emission area B-EA emitting blue light.

A micro-cavity structure to emit light having a specific wavelength can be formed in the emission area R-EA, G-EA and B-EA of each pixel area PA. For example, a reflective electrode 200R, 200G and 200B can be disposed between the driving circuit DC and the first electrode 310 of each pixel area PA. A color displayed by the light emitted from the emission area R-EA, G-EA and B-EA of each pixel area PA can be determined by the location of the reflective electrode 200R, 200G and 200B. For example, the device planarization layer 130 can include a first planarization layer 131 on the interlayer insulating layer 120, a second planarization layer 132 covering a red reflective electrode 200R of the red emission area R-EA on the first planarization layer 131, a third planarization layer 133 covering a green reflective electrode 200G of the green emission area G-EA on the second planarization layer 132, and a fourth planarization layer 134 surrounding a blue reflective electrode 200B of the blue emission area B-EA on the third planarization layer 133. An upper surface of the blue reflective electrode 200B opposite to the device substrate 100 can be in direct contact with the first electrode 310 disposed on the blue emission area B-EA.

A separating trench ST can be disposed between the fences 140. The separating trench ST can have a groove shape from which a portion of the device planarization layer 130 is removed. For example, an air-gap can be formed inside the separating trench ST. The light-emitting unit 320 of each pixel area PA can be partially separated from the light-emitting unit 320 of adjacent pixel area PA by the separating trench ST. For example, the light-emitting unit 320 of each pixel area PA can include emission stacks and at least one charge generation layer disposed between the emission stacks, the at least one charge generation layer disposed on each pixel area PA can be separated from the at least one charge generation layer disposed on adjacent pixel area PA by the separating trench ST. Thus, in the display apparatus according to the embodiment of the present disclosure, the leakage of the driving current through the at least one charge generation layer can be prevented.

An encapsulation structure 400 can be disposed on the light-emitting device 300 of each pixel area PA. The encapsulation structure 400 can prevent the damage of the light-emitting device 300 in each pixel area PA due to external impact and moisture. A thickness difference due to the light-emitting device 300 of each pixel area PA can be removed by the encapsulation structure 400. The encapsulation structure 400 can have a multi-layer structure. For example, the encapsulation structure 400 can include a first encapsulating layer 410, a second encapsulating layer 420 and a third encapsulating layer 430, which are sequentially stacked. The second encapsulating layer 420 can include a material having a higher fluidity than the first encapsulating layer 410 and the third encapsulating layer 430. For example, the first encapsulating layer 410 and the third encapsulating layer 430 can include an inorganic insulating material, and the second encapsulating layer 420 can include an organic insulating material. An upper surface of the encapsulation structure 400 opposite to the device substrate 100 can be flat.

Color filters 500R, 500G and 500B can be disposed on the encapsulation structure 400. Each of the color filters 500R, 500G and 500B can overlap the emission area R-EA, G-EA and B-EA of one of the pixel areas PA. Each of the color filters 500R, 500G and 500B can include a different material from adjacent color filter 500R, 500G and 500B. Light passing through the color filter 500R, 500G and 500B of each pixel area PA can display a same color as the light emitted by the micro-cavity structure formed in the corresponding pixel area PA. For example, the color filters 500R, 500G and 500B can include a red color filter 500R overlapping with the red emission area R-EA, a green color filter 500G overlapping with the green emission area G-EA and a blue color filter 500B overlapping with the blue emission area B-EA. Thus, in the display apparatus according to the embodiment of the present disclosure, the color reproducibility of each pixel area PA can be improved.

The color filters 500R, 500G and 500B can be disposed side by side. Each of the color filters 500R, 500G and 500B can have a larger size than the corresponding emission area R-EA, G-EA and B-EA. For example, a side surface of each color filter 500R, 500G and 500B can be in direct contact with a side surface of adjacent color filter 500R, 500G and 500B on the non-emission area NEA. Thus, in the display apparatus according to the embodiment of the present disclosure, the light leakage in which the light that does not pass through one of the color filters 500R, 500G and 500B can be prevented. Therefore, in the display apparatus according to the embodiment of the present disclosure, the quality of the image recognized by the user can be improved.

An optical planarization layer 600 can be disposed on the color filters 500R, 500G and 500B. The optical planarization layer 600 can prevent the damage of the color filters 500R, 500G and 500B due to the external impact. A thickness difference due to the color filters 500R, 500G and 500B can be removed by the optical planarization layer 600. For example, an upper surface of the optical planarization layer 600 opposite to the device substrate 100 can be flat. The optical planarization layer 600 can include an organic insulating material.

The amount of light passing through each color filter 500R, 500G and 500B can be different. For example, the amount of light passing through the blue color filter 500B can be smaller than the amount of light passing through the red color filter 500R and the amount of light passing through the green color filter 500G. A pixel lens 700 can be disposed between the optical planarization layer 600 and the color filter 500R, 500G and 500B through which a relative small amount of light passes. For example, in the display apparatus according to the embodiment of the present disclosure, the pixel lens 700 can be disposed between the blue color filter 500B of the blue emission area B-EA and the optical planarization layer 600, as shown in FIGS. 2, 4 and 5. A lower surface of the optical planarization layer 600 toward the device substrate 100 can include a region in contact with the red color filter 500R and a region in contact with the green color filer 500G.

A surface of the pixel lens 700 opposite to the device substrate 100 can have a convex shape. The optical planarization layer 600 covering the surface of the pixel lens 700 having a convex shape can have a smaller refractive index than the pixel lens 700. Thus, in the display apparatus according to the embodiment of the present disclosure, the light passing through the blue color filter 500B can be concentrated toward the center of the blue emission area B-EA by the pixel lens 700. That is, in the display apparatus according to the embodiment of the present disclosure, the frontal luminance of the blue emission area B-EA can be increased by the pixel lens 700. Therefore, in the display apparatus according to the embodiment of the present disclosure, the luminance deviation due to a difference in the amount of light passing through each color filter 500R, 500G and 500B can be reduced by the pixel lens 700. For example, in the display apparatus according to the embodiment of the present disclosure, the luminance deviation between blue color and red color which are recognized by the user and the luminance deviation between blue color and green color which are recognized by the user due to the relatively small amount of light passing through the blue color filter 500B can be reduced.

A lower surface of the pixel lens 700 toward the device substrate 100 can be in direct contact with an upper surface of the blue color filer 500B opposite to the device substrate 100. The lower surface of the pixel lens 700 can have a larger size than the blue emission area B-EA. For example, the lower surface of the pixel lens 700 can have a same size than the blue color filter 500B. An edge of the pixel lens 700 can overlap the non-emission area NEA.

An optical pattern 800 can be disposed between the edge of the pixel lens 700 and the optical planarization layer 600. The optical pattern 800 can include a reflective pattern 810 extending along the surface of the pixel lens 700 having a convex shape. The reflective pattern 810 can be in direct contact with the surface of the pixel lens 700 having a convex shape. The reflective pattern 810 can include a material having a relative high reflectance. For example, the reflective pattern 810 can include a metal, such as aluminum (Al) and silver (Ag). Thus, in the display apparatus according to the embodiment of the present disclosure, the light Lb1 passing through the upper surface of the blue color filter 500B and travelling toward adjacent red emission area R-EA or adjacent green emission area G-EA can be reflected toward the center of the blue emission area B-EA by the reflective pattern 810. That is, in the display apparatus according to the embodiment of the present disclosure, all light passing through the upper surface of the blue color filter 500B can be concentrated within the blue emission area B-EA by the pixel lens 700 and the reflective pattern 810. Therefore, in the display apparatus according to the embodiment of the present disclosure, the luminance deviation due to a difference in the amount of light passing through each color filter 500R, 500G and 500B can be effectively reduced.

The optical pattern 800 can include a light-blocking pattern 820 disposed on the reflective pattern 810. For example, the reflective pattern 810 can be disposed between the pixel lens 700 and the light-blocking pattern 820. The light-blocking pattern 820 can have a lower reflectance than the reflective pattern 810. For example, the light-blocking pattern 820 can include a low-reflective metal, such as titanium (Ti). Thus, in the display apparatus according to the embodiment of the present disclosure, the light not reflected by the reflective pattern 810 can be absorbed by the light-blocking pattern 820.

The light-blocking pattern 820 can extend along the reflective pattern 810. The light-blocking pattern 820 can have a larger size than the reflective pattern 810. For example, the reflective pattern 810 can be covered by the light-blocking pattern 820. The pixel lens 700 can include a region in direct contact with the reflective pattern 810. For example, an end of the light-blocking pattern 820 can be in direct contact with the pixel lens 700 at the outside of the reflective pattern 810. An upper surface of the red color filter 500R and an upper surface of the green color filter 500G, which are opposite to the device substrate 100 can include a region in contact with the light-blocking pattern 820. Thus, in the display apparatus according to the embodiment of the present disclosure, the light Lb2 travelling toward the upper surface of the red color filer 500R or the upper surface of the green color filter 500G through the blue color filter 500B can be absorbed by the light-blocking pattern 820. And, in the display apparatus according to the embodiment of the present disclosure, the light Lr passing through the upper surface of the red color filter 500R and travelling toward the pixel lens 700 and the light Lg passing through the upper surface of the green color filter 500G and travelling toward the pixel lens 700 can be blocked by the light-blocking pattern 820. That is, in the display apparatus according to the embodiment of the present disclosure, the refraction of the light Lr passing through the upper surface of the red color filter 500R and the refraction of the light Lg passing through the upper surface of the green color filter 500G at the surface of the pixel lens 700 having a convex shape can be prevented by the light-blocking pattern 820. Therefore, in the display apparatus according to the embodiment of the present disclosure, the change of the color coordinates due to the light refracted at the surface of the pixel lens having a convex shape can be prevented.

The reflective pattern 810 and the light-blocking pattern 820 of the optical pattern 800 can be disposed in the non-emission area NEA. For example, the emission areas R-EA, G-EA and B-EA can be disposed outside the optical pattern 800. That is, in the display apparatus according to the embodiment of the present disclosure, the reflective pattern 810 and the light-blocking pattern 820 of the optical pattern 800 can't overlap the emission areas R-EA, G-EA and B-EA. Thus, in the display apparatus according to the embodiment of the present disclosure, the luminance of blue color recognized by the user can be increased, without reducing the luminance of red color recognized by the user and the luminance of green color recognized by the user. Therefore, in the display apparatus according to the embodiment of the present disclosure, the luminance of the image provided to the user can be improved as a whole.

Accordingly, the display apparatus according to the embodiment of the present disclosure can comprise the light-emitting devices 300 disposed on the emission areas R-EA, G-EA and B-EA of the device substrate 100, the color filters 500R, 500G and 500B disposed on the light-emitting devices 300, the pixel lens 700 disposed on the blue color filter 500B, the optical pattern 800 covering the edge of the pixel lens 700, and the optical planarization layer 600 disposed on the color filters 500R, 500G and 500B, the pixel lens 700 and the optical pattern 800, wherein the optical pattern 800 disposed in the non-emission area NEA can have a stacked structure of the reflective pattern 810 and the light-blocking pattern 820. Thus, in the display apparatus according to the embodiment of the present disclosure, the luminance of blue color recognized by the user can be increased, without changing the color coordinates. That is, in the display apparatus according to the embodiment of the present disclosure, a difference in the amount of the light passing through each color filter 500R, 500G and 500B can be reduced by the pixel lens 700. Therefore, in the display apparatus according to the embodiment of the present disclosure, the luminance of the image recognized by the user can be improved as a whole.

And, in the display apparatus according to the embodiment of the present disclosure, a difference in the amount of the light passing through each color filter 500R, 500G and 500B can be compensated by the pixel lens 700. Thus, in the display apparatus according to the embodiment of the present disclosure, a voltage of the data signal applied to the driving circuit DC of the pixel area PA including the blue emission area B-EA can be reduced. Therefore, in the display apparatus according to the embodiment of the present disclosure, the low power driving can be possible, and the power consumption can be reduced.

The display apparatus according to the embodiment of the present disclosure is described that the driving circuit DC of each pixel area PA consists of the first thin film transistor TR1, the second thin film transistor TR2 and the storage capacitor Cst. However, in the display apparatus according to another embodiment of the present disclosure, the driving circuit DC of each pixel area PA can include a driving thin film transistor and at least one switching thin film transistor. For example, in the display apparatus according to another embodiment of the present disclosure, the driving circuit DC of each pixel area PA can further include a third thin film transistor to initialize the storage capacitor Cst of the corresponding pixel area PA according to the gate signal. Thus, in the display apparatus according to another embodiment of the present disclosure, the degree of freedom in the configuration of each driving circuit DC can be improved.

In the display apparatus according to the embodiment of the present disclosure, the location and the electric connection of the first drain electrode, the first source electrode, the second drain electrodes 225 and the second source electrode 227 of each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

The display apparatus according to the embodiment of the present disclosure is described that the device substrate 100 is a wafer formed of a semiconductor material, such as silicon. However, in the display apparatus according to another embodiment of the present disclosure, the device substrate 100 can include glass or plastic. For example, in the display apparatus according to another embodiment of the present disclosure, the driving circuit DC of each pixel area PA can be formed on a buffer insulating layer covering the upper surface of the device substrate 100. The first thin film transistor TR1 and the second thin film transistor TR2 of each pixel area PA can include a semiconductor pattern made of a semiconductor material. Thus, in the display apparatus according to another embodiment of the present disclosure, the degree of freedom in the material of the device substrate 100 and the configuration of each driving circuit DC can be improved.

The display apparatus according to the embodiment of the present disclosure is described that the pixel lens 700 and the optical pattern 800 are disposed on the pixel area PA including the blue emission area B-EA. However, in the display apparatus according to another embodiment of the present disclosure, the location of the pixel lens 700 can be changed according to the amount of the light passing through each color filter 500R, 500G and 500B. For example, in the display apparatus according to another embodiment of the present disclosure, the amount of light passing through the red color filter 500R can be smaller than the amount of light passing through the green color filter 500G and the amount of light passing through the blue color filter 500B, the pixel lens 700 and the optical pattern 800 can be disposed between the red color filer 500R and the optical planarization layer 600, and the lower surface of the optical planarization layer 600 can include a region in contact with the upper surface of the green color filter 500G and a region in contact with the upper surface of the blue color filter 500B. Thus, in the display apparatus according to another embodiment of the present disclosure, the degree of freedom in the material of the color filters 500R, 500G and 500B can be improved.

In the display apparatus according to the embodiment of the present disclosure, the pixel lens 700 can be formed in various ways. For example, in the display apparatus according to the embodiment of the present disclosure, the pixel lens 700 can be formed by a step of forming a lens material layer on the color filters 500R, 500G and 500B, a step of forming preliminary pattern on the lens material layer, a step of forming preliminary lens by a reflow process of the preliminary pattern, and a step of transferring the preliminary lens to the lens material layer by dry etching the preliminary lens and the lens material layer. Thus, in the display apparatus according to the embodiment of the present disclosure, the deformation of the pixel lens 700 due to a process of forming the optical pattern 800 can be prevented. For example, in the display apparatus according to the embodiment of the present disclosure, the pixel lens 700 can be formed of a material having less deformation due to heat. Therefore, in the display apparatus according to the embodiment of the present disclosure, the degree of freedom in the material of the optical pattern 800 can be improved.

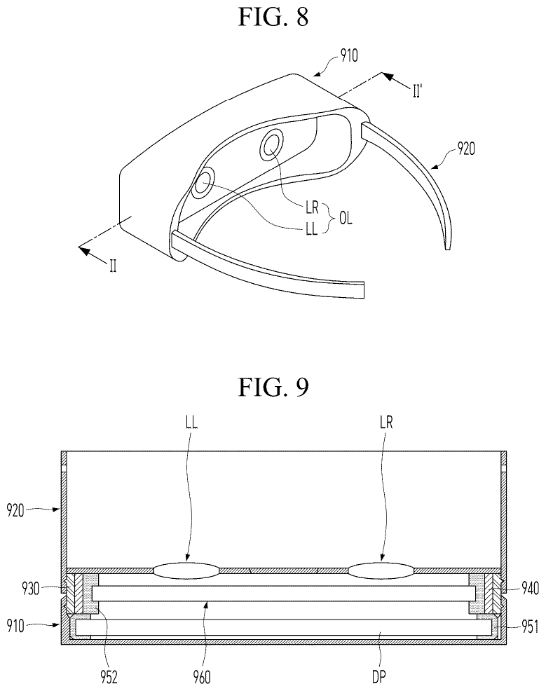

The display apparatus according to the embodiment of the present disclosure is described that the light-blocking pattern 820 includes a low-reflective metal. However, in the display apparatus according to another embodiment of the present disclosure, the light-blocking pattern 820 can include an insulating material. For example, in the display apparatus according to another embodiment of the present disclosure, the light-blocking pattern 820 can be formed of a black dye, such as carbon black or a relatively dark metal oxide, as shown in FIG. 6. Thus, in the display apparatus according to another embodiment of the present disclosure, the change of the color coordinates due to the light refracted at the surface of the pixel lens having convex shape can be effectively prevented. Therefore, in teh display apparatus according to the embodiment of the present disclosure, the degree of freedom in the material of the light-blocking pattern 820 can be improved.

The display apparatus according to the embodiment of the present disclosure is described that the reflective pattern 810 includes a metal. However, in the display apparatus according to another embodiment of the present invention, the reflective pattern 810 can be formed of various materials. For example, in the display apparatus according to another embodiment of the present disclosure, the reflective pattern 810 can be formed of a material having a very smaller refractive index than the optical planarization layer 600. That is, in the display apparatus according to another embodiment of the present disclosure, the light passing through the pixel lens 700 and travelling toward the reflective pattern 810 can be can be totally reflected at a boundary between the pixel lens 700 and the reflective pattern 810. Thus, in the display apparatus according to another embodiment of the present disclosure, the deformation of the pixel lens 700 due to a process of forming the reflective pattern 810 can be effectively prevented. And, in the display apparatus according to another embodiment of the present disclosure, the degree of freedom in a process of forming the pixel lens 700 can be improved.

In the display apparatus according to another embodiment of the present disclosure, the reflective pattern 810 and the light-blocking pattern 820 can be formed of an insulating material. Thus, in the display apparatus according to another embodiment of the present disclosure, a process of forming the reflective pattern 810 and a process of forming the light-blocking pattern 820 can be performed by a single mask. For example, in the display apparatus according to another embodiment of the present disclosure, a side surface of the reflective pattern 810 can be continuous with a side surface of the light-blocking pattern 820, as shown in FIG. 7. The reflective pattern 810 can have a same size as the light-blocking pattern 820 within the non-emission area NEA. For example, the reflective pattern 810 can extend between the upper surface of the red color filter 500R non-overlapping with the pixel lens 700 and the light-blocking pattern 820 or the upper surface of the green color filter 500G non-overlapping with the pixel lens 700 and the light-blocking pattern 820. Therefore, in the display apparatus according to another embodiment of the present disclosure, the degree of freedom in a process of forming the optical pattern 800. And, in the display apparatus according to another embodiment of the present disclosure, the process efficiency can be improved.

In the display apparatus according to another embodiment of the present disclosure, the display panel DP can be used in various electronic devices. For example, the display apparatus according to another embodiment of the present disclosure can be a head mounted display (HMD) apparats in which the display panel DP is accommodated in an image element 910 and the image element 910 is fixed in front of the user's eyes by a mounting element 920, as shown in FIGS. 8 and 9. The mounting element 920 can have a shape, such as a leg of a spectacle frame. For example, the mounting element 920 can have a shape extending in a direction from an edge of the image element 910. The mounting element 920 can be coupled to, the image element 910 by a coupling element 930. For example, the coupling element 930 can have a plate shape including a region coupled to the image element 910 and a region coupled to the mounting element 920. The coupling element 930 can be disposed inside the image element 910 and the mounting element 920.

The eyepiece lenses OL disposed on a side of the image element 910 can include a left-eye lens LL disposed in front of the user's left eye, and a right-eye lens LR disposed in front of the user's right eye. An empty space can be disposed between the display panel DP and the eyepiece lenses OL. For example, the display panel DP can be disposed close to a first surface of the image element 910, and the left-eye lens LL and the right-eye lens LR can be fixed at a second surface of the image element 910 opposite to the first surface of the image element 910. A gap maintaining element 940 can be disposed inside the coupling element 930 to maintain a space between the display panel DP and the eyepiece lenses OL. The gap maintaining element 940 can be disposed parallel to the coupling element 930. For example, the gap maintaining element 940 can be in direct contact with the coupling element 930.

A first fixing element 951 to fix the display panel DO can be disposed in the image element 910. For example, the first fixing element 951 can be in direct contact with the first surface of the image element 910. Thus, in the display apparatus according to another embodiment of the present disclosure, the movement of the display panel DP and the eyepiece lenses OL according to the user's movement can be effectively prevented. Therefore, in the display apparatus according to another embodiment of the present disclosure, the visibility of the image recognized by the user can be improved.

In the display apparatus according to another embodiment of the present disclosure, the image by the display panel DP and an actual object disposed beyond the first surface of the image element 910 can be provided simultaneously to the user. For example, at least one optical lens 960 can be disposed between the display panel DP and the eyepiece lenses OL. The at least one optical lens 960 can be spaced apart from the display panel DP and the eyepiece lens OL. For example, a second fixing element 952 to fix the at least one optical lens 960 can be disposed in the image element 910. The image by the display panel DP can be displayed on an actual object disposed in front of the user by the at least one optical lens 960. Thus, in the display apparatus according to another embodiment of the present disclosure, an accident due to blocking the user's view can be prevented.

The display apparatus according to another embodiment of the present disclosure is described that the mounting element 920 has a shape, such as a leg of a spectacle frame. However, in the display apparatus according to another embodiment of the present disclosure, the mounting element 920 can have various shapes. For example, in the display apparatus according to another embodiment of the present disclosure, the mounting element 920 can have a head gear shape surrounding the user's head. Thus, in the display apparatus according to another embodiment of the present disclosure, the degree of freedom in a type of the electronic devices in which the display panel DP is used can be improved.

In the result, the display apparatus according to the embodiments of the present disclosure can comprise the light-emitting devices disposed on the emission areas of the device substrate, the color filters disposed on the light-emitting devices, the pixel lens disposed on one of the color filters, the optical pattern covering the edge of the pixel lens, and the optical planarization layer disposed on the color filters, the pixel lens and the optical pattern, wherein the optical pattern can include the reflective pattern and the light-blocking pattern disposed on the reflective pattern, and wherein the reflective pattern and the light-blocking pattern of the optical pattern can't overlap the emission areas. Thus, in the display apparatus according to the embodiments of the present disclosure, a difference in the amount of the light passing through each color filter can be reduced by the pixel lens, without the change of the color coordinates. Thereby, in the display apparatus according to the embodiments of the present disclosure, the quality of the image recognized by the user can be improved. And, in the display apparatus according to the embodiments of the present disclosure, the low power driving can be possible, and the power consumption can be reduced.

It will be apparent to those skilled in the art that various modifications and variations can be made in the display apparatus having light-emitting devices and color filters of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display apparatus, comprising:
light-emitting devices on emission areas of a device substrate;
color filters on the light-emitting devices, the color filters overlapping with the emission areas;
a pixel lens on one of the color filters, a surface of the pixel lens opposite to the device substrate having a convex shape;
an optical pattern in a non-emission area disposed between the emission areas, the optical pattern covering an edge of the pixel lens; and
an optical planarization layer on the color filters, the pixel lens and the optical pattern,
wherein the optical pattern includes a reflective pattern and a light-blocking pattern disposed on the reflective pattern.

2. The display apparatus according to claim 1, wherein the reflective pattern is in contact with the surface of the pixel lens having a convex shape.

3. The display apparatus according to claim 1, wherein the light-blocking pattern has a larger size than the reflective pattern.

4. The display apparatus according to claim 3, wherein the reflective pattern is covered by the light-blocking pattern.

5. The display apparatus according to claim 3, wherein the reflective pattern includes a metal.

6. The display apparatus according to claim 5, wherein the light-blocking pattern includes a low-reflective metal having a lower reflectivity than the reflective pattern.

7. The display apparatus according to claim 1, wherein the color filters include different materials.

8. The display apparatus according to claim 7, wherein a lower surface of the pixel lens toward the device substrate has a same size as the corresponding color filter.

9. A display apparatus, comprising:
a first light-emitting device on a first emission area of a device substrate;
a second light-emitting device on a second emission area of the device substrate;
a first color filter on the first light-emitting device, the first color filter overlapping with the first emission area;
a second color filter on the second light-emitting device, the second color filter overlapping with the second emission area;
an optical planarization layer on the first color filter, the optical planarization layer extending on the second color filter;
a pixel lens disposed between the second color filter and the optical planarization layer, a surface of the pixel lens toward the optical planarization layer having a convex shape; and
an optical pattern including a reflective pattern and a light-blocking pattern, which are sequentially stacked between the pixel lens and the optical planarization layer,
wherein the first emission area and the second emission area are disposed outside the optical pattern.

10. The display apparatus according to claim 9, wherein the optical planarization layer is in contact with an upper surface of the first color filter opposite to the device substrate.

11. The display apparatus according to claim 9, wherein a side surface of the second color filter is in contact with a side surface of the first color filter between the first emission area and the second emission area.

12. The display apparatus according to claim 11, wherein the optical pattern includes a region in contact with the first color filter between the first emission area and the second emission area.

13. The display apparatus according to claim 9, wherein the refractive index of the optical planarization layer is smaller than the refractive index of the pixel lens, and
wherein the reflective pattern includes an insulating material having a smaller refractive index than the optical planarization layer.

14. The display apparatus according to claim 13, wherein a side surface of the reflective pattern is continuous with a side surface of the light-blocking pattern.

15. The display apparatus according to claim 9, wherein the light-blocking pattern includes an insulating material.
